(19) United States
(12) Patent Application Publication
(10) Pub. No.: US 2018/0095929 A1
(43) Pub. Date: Apr. 5, 2018

(54) SCRATCHPAD MEMORY WITH BANK TILING FOR LOCALIZED AND RANDOM DATA ACCESS

(71) Applicant: INTEL CORPORATION, Santa Clara, CA (US)

(72) Inventors: Zoran Zivkovic, 's-Hertogenbosch (NL); Aleksandar Beric, Eindhovenn (NL)

(73) Assignee: Intel Corporation, Santa Clara, CA (US)

(21) Appl. No.: 15/281,376

(22) Filed: Sep. 30, 2016

(51) Int. Cl. G06F 15/173; G11C 7/22; G11C 7/10; G06F 3/06; G06F 13/42

(52) U.S. Cl. CPC G06F 15/17318; G11C 7/22; G11C 7/1057; G06F 3/0613; G06F 13/4234; G06F 3/0659; G06F 3/0683; G06F 13/4286; G06F 3/0656

(57) ABSTRACT

An apparatus for localized and random data access is described herein. The apparatus includes a multi-bank memory, a queue, and an output buffer. The multi-bank memory is to store addresses locations of imaging data. The queue corresponds to each bank of the multi-bank memory, and the queue is to store addresses from the multi-bank memory for data access. The output buffer is to store data accessed based on addresses from the queue.

### BACKGROUND ART

Modern processors, such as digital signal processors (DSPs) can perform many operations in parallel. The large computational abilities of modern DSPs can only be utilized if the DSP is able to transmit and receive enough data for parallel operations. A memory with a large bandwidth is used to transmit and receive enough data to modern processors. However, various applications can access data in memory in a random and unpredictable manner.

### BRIEF DESCRIPTION OF THE DRAWINGS

FIG. 1 is a block diagram of a computing device that enables memory bank tiling for localized and random data access;

FIG. 2 is an illustration of data access patterns;

FIG. 3 is an illustration of data operations according to the present techniques;

FIG. 4 is an illustration of a memory and memory bank addressing;

FIG. 5 is an illustration of a memory with skewed memory bank addressing;

FIG. 6 is a block diagram of a read operation;

FIG. 7 is a block diagram of a write operation;

FIG. 8 is a process flow diagram of a method for localized and random data access;

FIG. 9 is a process flow diagram of a method for localized and random data access;

FIG. 10 is a block diagram showing tangible, non-transitory computer-readable media that stores code for localized and random data access; and

FIG. 11 is a chart illustrating the performance of three example random data memory types.

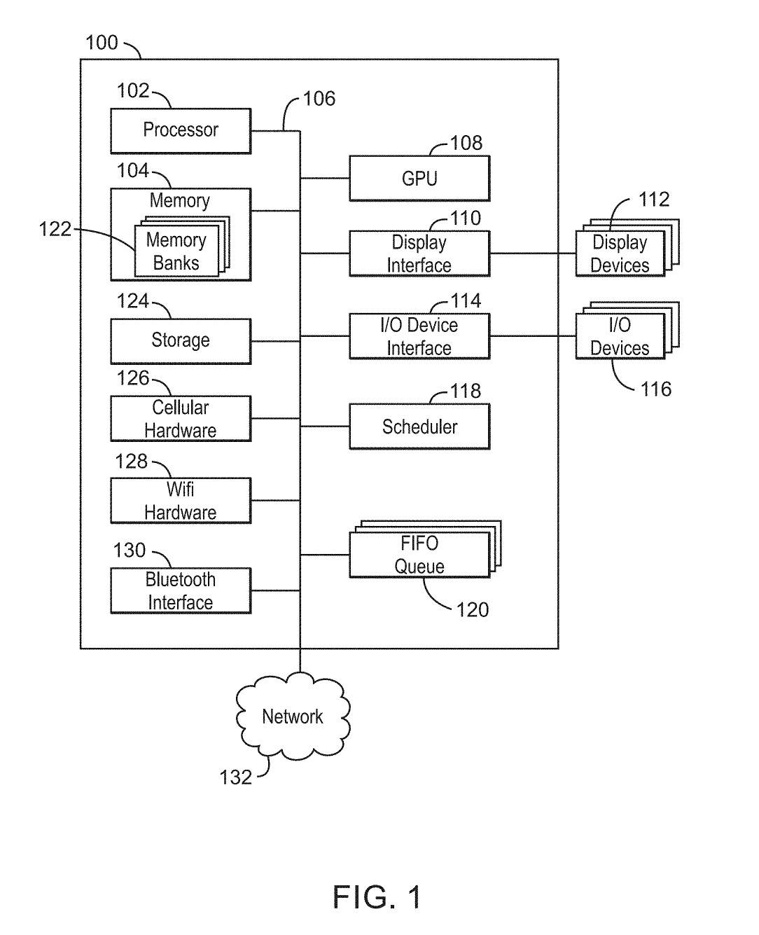

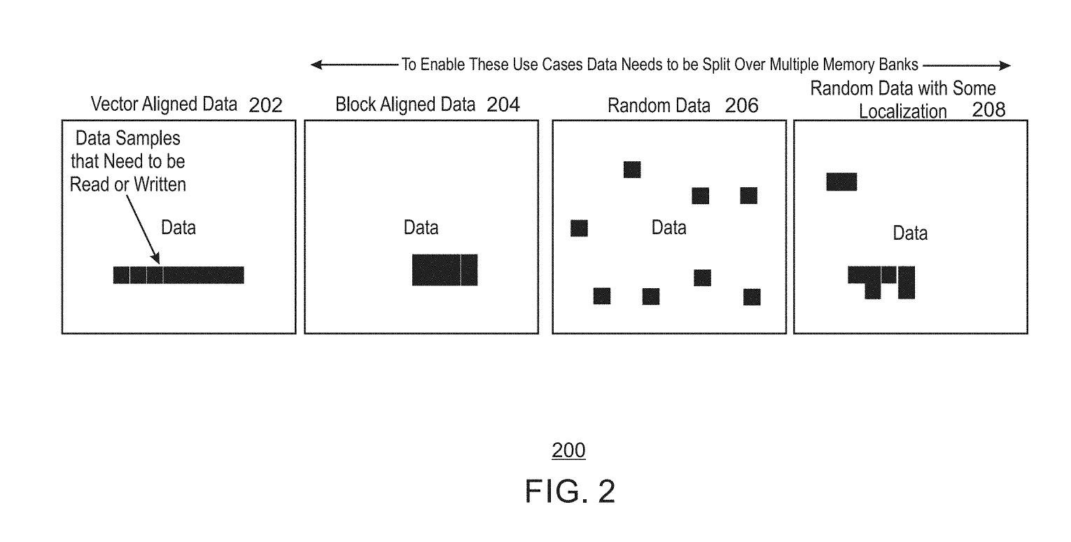

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

Based on, at least in part, the parallelism present in modern processors, these processors are able to quickly process a large amount of data. Addressable memory banks can be used to supply the processors with the data. Processing can be limited by how quickly data can be retrieved from the memory bank, as well as the amount of data that can be retrieved from the memory bank per clock cycle. Memory bandwidth refers to the amount of data that can be written or retrieved from the memory at one time, typically once per clock cycle. A memory with a large bandwidth may refer to a vector access memory or a memory capable of transferring more bits per second than presently available memory chips.

With high bandwidth memory, instead of reading a single data element at time, a typical large bandwidth memory could read NWAY data elements in one clock cycle. As used herein, NWAY may refer to the width of a single instruction multiple data (SIMD) of the vector processor (VP). In embodiments, an image processing unit (IPU) includes a VP that is a programmable SIMD core, built to enable a firmware solution. The IPU may be a flexible, after-the-silicon answer to various application needs. Many IPUs are designed where NWAY=32, however NWAY may also be 16, 64, 128, or any other value. Typical memory design enables reading NWAY samples in parallel only if they are next to each other and aligned to a specified address grid, wherein memory access is logically organized as a square or rectangle with a number of rows and columns.

Embodiments described herein relate generally to memory organization and addressing. More specifically, the present invention relates to memory organization and scheduling combined with or without skewed addressing. In various embodiments, a multi-bank memory is to store addresses locations of imaging data. A queue may corresponds to each bank of the multi-bank memory, and the queue is to store addresses from the multi-bank memory for data access. An output buffer is to store data accessed based on addresses from the queue. The present techniques include a hardware solution for imaging, computer vision, and/or machine learning. In embodiments, a memory design may be implemented for an image processing unit (IPU) digital signal processor (DSP) that enables also reading NWAY samples if they are organized as a two dimensional (2D) block. This may be achieved using skewed addressing as described herein.

Modern computational imaging, computer vision and machine learning algorithms require access to individual data samples scattered around the memory in a random fashion. Current memories however would provide on average only one random sample per clock cycle and cause very poor utilization of the large computational DSP parallelism described above. The present techniques organize and schedule data such that a memory subsystem is to deliver a vector of NWAY samples, within a minimal amount of clock cycles. Addressing may be skewed such that the vector aligned data and random data can be accessed in a minimum number of clock cycles. Data access in the same memory system may be relatively quick, even when the data is block aligned or random data with some localization.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine, e.g., a computer. For example, a machine-readable medium may include read only memory (ROM); random access memory (RAM); magnetic disk storage media; optical storage media; flash memory devices; or electrical, optical, acoustical or other form of propagated signals, e.g., carrier waves, infrared signals, digital signals, or the interfaces that transmit and/or receive signals, among others.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the inventions. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

FIG. 1 is a block diagram of a computing device that enables memory bank tiling for localized and random data access. The computing device 100 may be, for example, a laptop computer, tablet computer, mobile phone, smart phone, or a wearable device, among others. The computing device 100 may include a central processing unit (CPU) 102 that is configured to execute stored instructions, as well as a memory device 104 that stores instructions that are executable by the CPU 102. The CPU may be coupled to the memory device 104 by a bus 106. Additionally, the CPU 102 can be a single core processor, a multi-core processor, a computing cluster, or any number of other configurations. Furthermore, the computing device 100 may include more than one CPU 102. The memory device 104 can include random access memory (RAM), read only memory (ROM), flash memory, or any other suitable memory systems. For example, the memory device 104 may include dynamic random access memory (DRAM).

The computing device 100 also includes a graphics processing unit (GPU) 108. As shown, the CPU 102 can be coupled through the bus 106 to the GPU 108. The GPU 108 can be configured to perform any number of graphics operations within the computing device 100. For example, the GPU 108 can be configured to render or manipulate graphics images, graphics frames, videos, or the like, to be displayed to a user of the computing device 100. In some embodiments, the GPU 108 includes a number of graphics engines, wherein each graphics engine is configured to perform specific graphics tasks, or to execute specific types of workloads. For example, the GPU 108 may include an engine that processes video data.

The CPU 102 can be linked through the bus 106 to a display interface 110 configured to connect the computing device 100 to a display device 112. The display device 112 can include a display screen that is a built-in component of the computing device 100. The display device 112 can also include a computer monitor, television, or projector, among others, that is externally connected to the computing device 100.

The CPU 102 can also be connected through the bus 106 to an input/output (I/O) device interface 114 configured to connect the computing device 100 to one or more I/O devices 116. The I/O devices 116 can include, for example, a keyboard and a pointing device, wherein the pointing device can include a touchpad or a touchscreen, among others. The I/O devices 116 can be built-in components of the computing device 100, or can be devices that are externally connected to the computing device 100.

The computing device 100 also includes a scheduler 118 for scheduling the read/write of data to memory. In embodiments, each address is added to a FIFO queue 120 of the corresponding memory bank, rather than collecting and scheduling an entire set of addresses. Accordingly, the addresses may be added to the plurality of FIFO queues 120 in a streaming or continuous mode. Each queue of the plurality of FIFO queues 120 may correspond to a memory bank 122 of the memory 104.

The computing device may also include a storage device 124. The storage device 124 is a physical memory such as a hard drive, an optical drive, a flash drive, an array of drives, or any combinations thereof. The storage device 124 can store user data, such as audio files, video files, audio/video files, and picture files, among others. The storage device 124 can also store programming code such as device drivers, software applications, operating systems, and the like. The programming code stored to the storage device 124 may be executed by the CPU 102, GPU 108, or any other processors that may be included in the computing device 100.

The CPU 102 may be linked through the bus 106 to cellular hardware 126. The cellular hardware 126 may be any cellular technology, for example, the 4G standard (International Mobile Telecommunications-Advanced (IMT-Advanced) Standard promulgated by the International Telecommunications Union—Radio communication Sector (ITU-R)). In this manner, the PC 100 may access any network 132 without being tethered or paired to another device, where the network 132 is a cellular network.

The CPU 102 may also be linked through the bus 106 to WiFi hardware 128. The WiFi hardware is hardware according to WiFi standards (standards promulgated as Institute of Electrical and Electronics Engineers' (IEEE) 802.11 standards). The WiFi hardware 128 enables the computing device 100 to connect to the Internet using the Transmission Control Protocol and the Internet Protocol (TCP/IP), where the network 132 is the Internet. Accordingly, the computing device 100 can enable end-to-end connectivity with the Internet by addressing, routing, transmitting, and receiving data according to the TCP/IP protocol without the use of another device. Additionally, a Bluetooth Interface 130 may be coupled to the CPU 102 through the bus 106. The Bluetooth Interface 130 is an interface according to Bluetooth networks (based on the Bluetooth standard promulgated by the Bluetooth Special Interest Group). The Bluetooth Interface 130 enables the computing device 100 to be paired with other Bluetooth enabled devices through a personal area network (PAN). Accordingly, the network 132 may be a PAN. Examples of Bluetooth enabled devices include a laptop computer, desktop computer, ultrabook, tablet computer, mobile device, or server, among others.

The block diagram of FIG. 1 is not intended to indicate that the computing device 100 is to include all of the components shown in FIG. 1. Rather, the computing system 100 can include fewer or additional components not illustrated in FIG. 1 (e.g., sensors, power management integrated circuits, additional network interfaces, etc.). The computing device 100 may include any number of additional components not shown in FIG. 1, depending on the details of the specific implementation. Furthermore, any of the functionalities of the CPU 102 may be partially, or entirely, implemented in hardware and/or in a processor. For example, the functionality may be implemented with an application specific integrated circuit, in logic implemented in a processor, in logic implemented in a specialized graphics processing unit, or in any other device.

As discussed above, the memory of the electronic device may comprise a plurality of memory banks as opposed to a monolithic memory bank. A scratchpad memory may provide a multi-level buffering of video data from an image memory. The size of the scratchpad may be selected as being larger than the total memory banks. Thus, the scratchpad memory may include the plurality of memory banks. The memory banks each have a plurality of addressable locations where each location is arranged to store a plurality of addresses.

To facilitate random data accesses, a memory architecture may include data that is split into multiple memory banks. A buffer of addresses is kept in the memory. Based on the randomness of the data access, the data read/write operations can be reordered in time such that a very high data throughput can be achieved. The data may be streamed using an efficient streaming scheduling mechanism.

In embodiments, the memory organization and scheduling can be combined with skewed addressing. In some cases, skewed addressing may also be applied to an IPU block access (BA) memory. The skewed addressing enables further optimization for various data patterns enabling efficient access for both random samples and the samples grouped in blocks or other localized patterns.

For example, instead of using single monolithic memory bank, data is split into multiple memory banks. Let the number of banks be denoted by Nb. Assume that Na is the number addresses in a set of random addresses for read or write operations. The random addresses can be reordered and scheduled to achieve very high memory data throughput in realistic applications. An efficient streaming scheduling mechanism can be introduced for a memory structure including the reordered and scheduled random addresses.

To further achieve very high memory data throughput, the present techniques implement special patterns while writing multidimensional data into the memory. The patterns result in an increase the average performance of accessing some shapes (memory access patterns) in parallel. In embodiments, samples organized in blocks or grouped together can be accessed very efficiently by minimizing the chance they are in the same memory bank. Samples from same memory bank may be organized in distinct access patterns such that for each write, the chance that more than one sample is accessed from the same memory bank is minimized. While access according to memory access patterns is optimized, at the same time efficient random access is retained.

Standard memory design simply allows reading NWAY samples in parallel only if they are aligned. In some cases, N samples can be read or written to the IPU if they are organized as a two dimensional (2D) block, also known as block access. Thus, with block access the memory can be read as 1×32, 2×16, 4×8, etc. blocks from the 2D data space. A scheduling mechanism for the read/write operations as described herein is presented for applications requiring streaming/continuous data access. The present techniques will reduce the latency of the data read/write with respect to data scheduling in a burst mode. The present techniques are not required to be aligned to a vector grid. Rather, the present techniques take advantage of a memory architecture that enables high throughput on random address data access combined with an efficient scheduling mechanism. Simulations show average increase of throughput 30% increase with respect to data retrieval in a burst mode, and also fourteen times increase with respect to typical large bandwidth memories.

Further combined with skewed addressing described herein, the present techniques enable efficient access of the data samples that are randomly distributed, within 1D or 2D shapes, or blocks, or other localized patterns. Current memory architectures do not enable such a wide pattern of data accesses, such as the randomly distributed, within 1D or 2D shapes, or blocks, or other localized patterns. The proposed architecture enables wide range of data patterns that can be accessed efficiently.

FIG. 2 is an illustration of data access patterns 200. In embodiments, the present techniques may read/write data according to the patterns 200. However, the present techniques are not limited to the data patterns described herein. Data patterns include a vector aligned data pattern 202, a block aligned data pattern 204, a random data pattern 206, and a random data with some localization 208. In the vector aligned data 202, data is organized in a one dimensional (1D), linear format. In embodiments, an additional constraint is that only allowed accesses to this data are aligned to the vector grid. Horizontally, accesses are possible only in multiples of NWAY (vector size). Data pattern 204 has similar constraint, with the only difference that the data can be organized as 2D shape. In the random data 206, data is placed by chance, in a random fashion. In the random data with some localization 208, data is localized and random. A group of samples, exhibiting geometrical localization, can clearly be identified, in this case.

Regular high bandwidth memory, such as vector access memory on an IPU using a single memory bank can easily access vector-aligned data 202, but is inefficient with other data patterns 204-208. Special access block memory, such as block access memory of an IPU, is efficient for vector-aligned data 202 and block-aligned data 204 but suffers with other data patterns 206-208.

While vector aligned data 202 and block aligned data 204 are common in image processing, random data access patterns and localized-random data access patterns 206-208 are common in computer vision, machine learning and computational photography applications. The present techniques enable efficient access for all data patterns 202-208. Furthermore, the present techniques also enable efficient random access with some level of localization, which is common for various object tracking and detection computer vision applications.

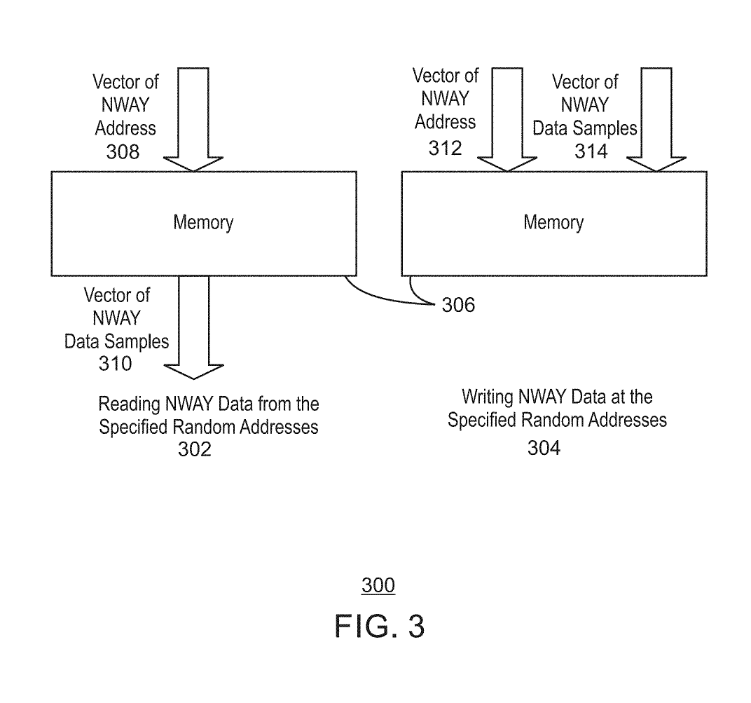

FIG. 3 is an illustration of data operations 300 according to the present techniques. The data operations 300 include a reading operation 302 and a writing operation 304. The memory 306 typically will receive NWAY addresses. In the case of the read operations 302, NWAY data samples 310 will be provided after certain number of clock cycles based on a vector of NWAY addresses. In case of the write operation 304, NWAY data samples 314 will also be written to the NWAY addresses 312.

The data may be split into Nb memory banks. Assume that the data is 2D data, such as an image, with width w. The address of the ith data sample is denoted as A[i]. The corresponding bank index will be denoted by b[i], a number in range 0 . . . Nb−1. There are various ways to split data into different banks. For example the bank index for address A[i] could be computed as

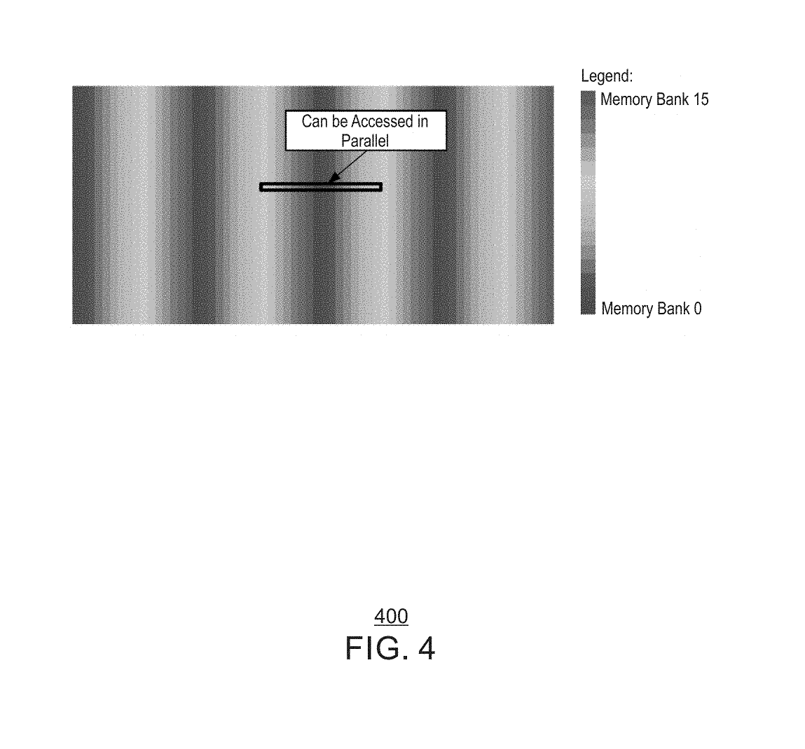

b[i]=mod(A[i],Nb)

where mod is a modulus operation. In case of a 32×64 memory, the data may then be split into memory banks as shown in FIG. 4.

FIG. 4 is an illustration of a memory 400 and memory bank addressing. As illustrated in the legend 402, a total of sixteen memory banks 404A . . . 404P are illustrated. In particular, the memory includes memory bank 0 404A . . . memory bank 15 404P. As illustrated, data from separate banks memory bank 0 404A . . . memory bank 15 404P can be accessed in parallel. While sixteen memory banks are illustrated, any number of memory banks may be used. Any horizontally aligned set of 16 samples, such as sample 406 can be accessed in parallel, as illustrated above.

In embodiments, the data may be organized in the memory banks according to skewed address logic. Skewed address logic is logic that is capable of adding an offset to each address. In embodiments, skewed address logic is to offset addresses to also efficient reading. Further, skewed address logic means that the linear data is not stored to neighboring addresses. Instead, there are jumps in address space, during storing the data, and this enables efficient, non-conflicting reads of 1D and 2D shapes of samples, un-aligned. The skewed address logic will allow efficient access to data when it is random or pseudo-random, but still localized in one dimensional (1D) or two dimensional (2D) shapes or patterns.

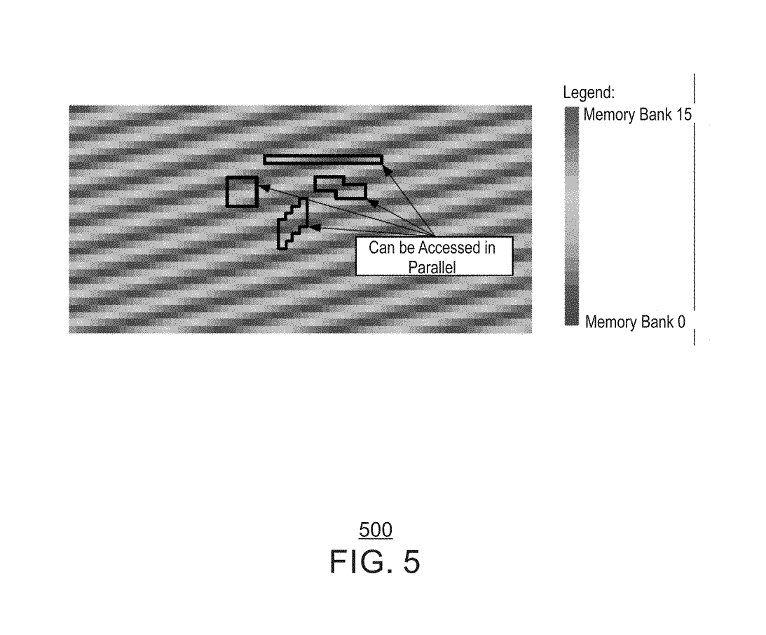

FIG. 5 is an illustration of a memory 500 with skewed memory bank addressing. In skewed address logic, each new row of data is shifted when writing the data. For example, for each new row of the data, the memory bank may be shifted index by a skew factor nSkew. Let iRow[i] be the 2D matrix row of the address A[i]. In an exemplary 32×64 use case, the addressing skew nSkew[i] could be nSkew[i]=4*iRow[i]. This means that for each new row of the data 2D matrix, the memory bank addressing is shifted by factor four. For the address A[i], the memory bank number becomes b[i]=mod(A[i]+nSkew[i], Nb). It is important to note that to enable such skew control it is necessary to know the shape of the multidimensional array and the position within the array. In the example here it is the knowledge of the iRow[i].

The same 32×64 data as FIG. 4, will now be split over memory banks as shown in FIG. 5. Note that the same data can now be accessed in many different ways. Some example shapes of the data address patterns that can be accessed in parallel are shown at reference number 504, 506, 508, and 510. In embodiments, each data access pattern will read/write data in each of the memory banks 502.

Various skewed addressing can be applied to the memory according to the techniques described herein. Skewed addressing enables efficient access to the elements close both in horizontal and vertical direction in a 2D data matrix. Knowledge of the data matrix size, e.g. width, is needed to apply this manner of data organization. The principle can also be applied to a three dimensional (3D) matrix or ND matrix, where N is the number of dimensions. With each dimension, an additional address offset needs to be added. The additional offset enables accessing, for example, a 3D cube of data in parallel. As used herein, the matrix refers to the address space that includes the memory banks to store addresses.

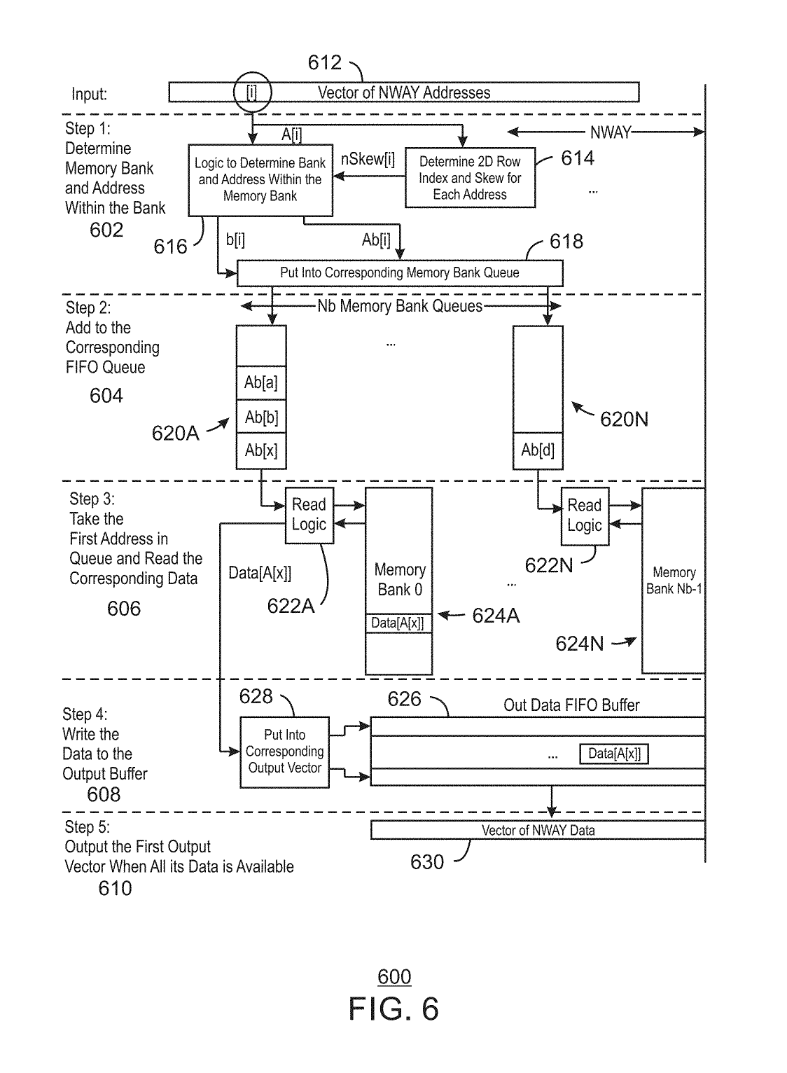

FIG. 6 is a block diagram of a reading operation. In embodiments, memory skewing is initialized and computed for each address A[i]. At block 602, the memory bank and addresses within the bank are determined. At block 604, the address is added to a corresponding first in, first out (FIFO) queue. At block 606, the first address in the queue is obtained and the corresponding data is read. At block 608, the data is written to the output buffer. At block 610, the first output vector is output when all of its data is available.

In embodiments, the dimensions of the matrix are used at setup to determine how nSkew[i] is calculated. A vector of NWAY addresses is used as input. At block 614, for each address A[i], the corresponding nSkew[i] is determined. At block 616, based on nSkew[i], the address bank b[i] and the address within that memory bank Ab[i] is determined. The address bank b[i] and the address within that memory bank Ab[i] may be placed into a corresponding memory bank queue at block 618.

At block 604, the address Ab[i] is placed into the FIFO queues 620 for its corresponding memory bank. At block 606, read logic 622 obtains the first address in the queue and reads the corresponding data from the memory bank 624 indicated by the address. Each memory bank takes the first in queue address, denoted by Ab[x] from its queue and delivers the corresponding data sample Data[A[x]]. After those steps, the data samples are extracted from the memory banks and there are various ways to deliver data.

In embodiments, the data may be delivered in the same order as requested by the set of addresses. Since data is read to optimize the parallel reading from the memory banks, it may not arrive in the same order as the set of addresses. However, an output data FIFO buffer 626 can enable returning the data to the same order. For each data, the present techniques may keep track of the position to which the data should be returned. Logic at block 628 may be the data in the proper position in the buffer 626. In case addresses arrive as NWAY vectors, which data vector may be determined first, and then which position in the vector. The procedure above can be extended by putting the data sample Data[A[x]] in its corresponding vector and position within the vector in the output buffer at block 628. Once the first in the FIFO buffer data vector is complete, output the NWAY data vector 630.

In embodiments, the data can be delivered in any order requested by the set of addresses. In this case, the data delivery can be simpler and more efficient. As soon as NWAY data is obtained it can be delivered. In such an embodiment, at block 608, the data sample Data[A[x]] is added to a single output NWAY. Once the buffer has NWAY data, return that vector, potentially accompanied with addresses or the index of addresses that those samples correspond to at block 610. In addition to the two data delivery technique described above, there can be other ways of delivering data. For example, every fixed number of clock cycles data can be delivered that is available at that point. This data can be accompanied for example by a binary mask describing which samples are available.

In embodiments, if the requested addresses form a block that can be accessed efficiently in parallel then high throughput will be achieved automatically. If a fixed block access pattern is used, then an address of the block can be supplied as scalar (the same way as now in an IPU block access memory) and internal logic can be used to calculate the addresses and memory banks. The number of clock cycles needed to read the data in that case will be fixed and predetermined so the memory will behave in the same way as the IPU block access memory.

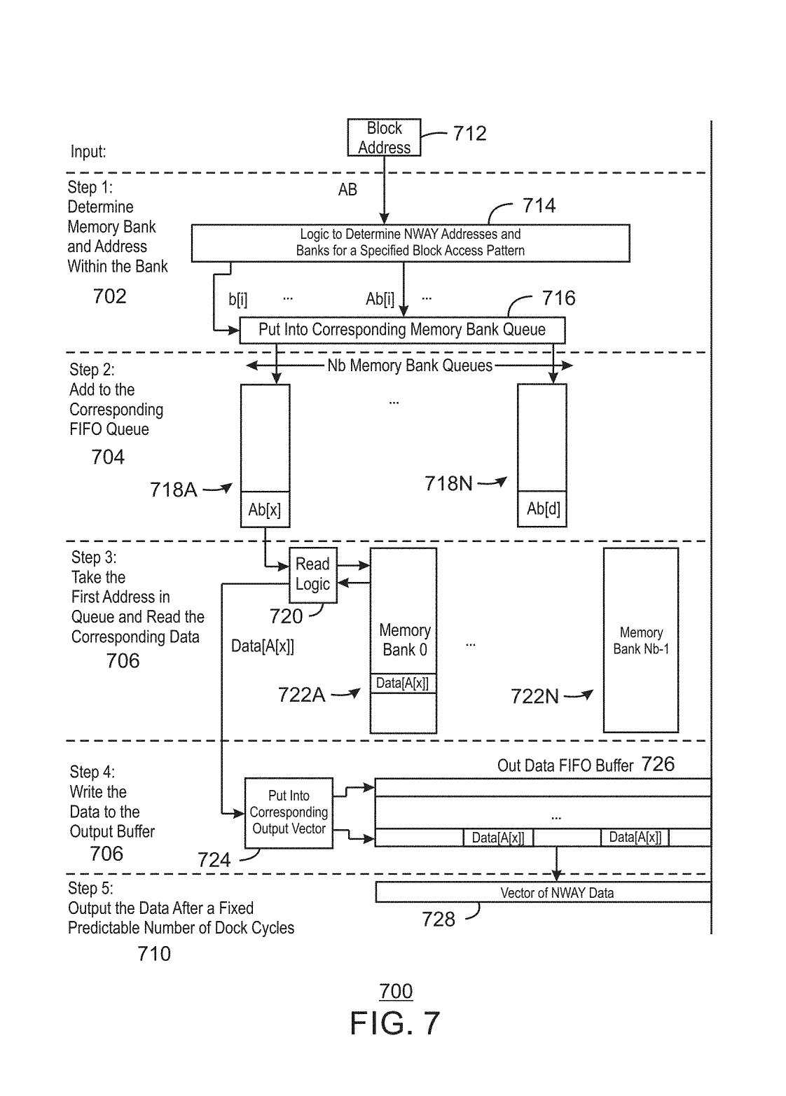

FIG. 7 is a block diagram of a write operation 700. For the write operation similar procedure can be applied without the additional complications of the order of data delivery. Similar to the write operation, the 2D (or higher dimensional) matrix dimensions are used at the setup to determine how nSkew[i] is calculated. At block 712, NWAY addresses and NWAY data points are used as input. At block 702, the memory bank and address within the memory bank is determined. For each address A[i], the corresponding nSkew[i] is determined and based on that the address bank b[i] and the address within that memory bank Ab[i]. Accordingly, at block 714, logic is to determine NWAY addresses and banks for a specified block access pattern. At block 716, the addresses are put into a corresponding memory bank queue.

At block 704, the addresses Ab[i] are added to the corresponding FIFO queue. In particular, the address Ab[i] is added into the FIFO queue 718A . . . 718N for its corresponding memory bank. Additionally, the corresponding data sample Data[i] is added to the FIFO. At block 706, the first address in the FIFO queue is obtained and used to read the corresponding data. The first address may be obtained using read logic 720. Each memory bank 722A . . . 722N takes the first in queue address denoted by Ab[x] from its queue and writes the corresponding data sample Data[i]. If a fixed block pattern access is used, the write addresses and banks can be computed by internal logic based on a scalar block address.

At block 708, data is written to the output buffer 726. Logic 724 may be used to place the data into a corresponding output vector. At block 710, the data may be output after a fixed, predictable number of clock cycles. The data may be output as a vector of NWAY data 728. In embodiments, if a fixed block pattern access is used the data will arrive after a fixed number of clock cycles. For the random access there are synchronization considerations. In particular, since the data access is random it cannot be guaranteed when certain data will be available. In the worst case all the addresses will be from the same bank and then they will be read sequentially.

The sizes of the FIFO queues for the memory banks need to be limited so they might get full. This can happen especially if addresses arrive in NWAY groups. If the queues get full than the memory cannot accept more address requests before they get emptied such that they can accept at least NWAY new addresses. As result the memory will require a signal to notify the processor about the availability.

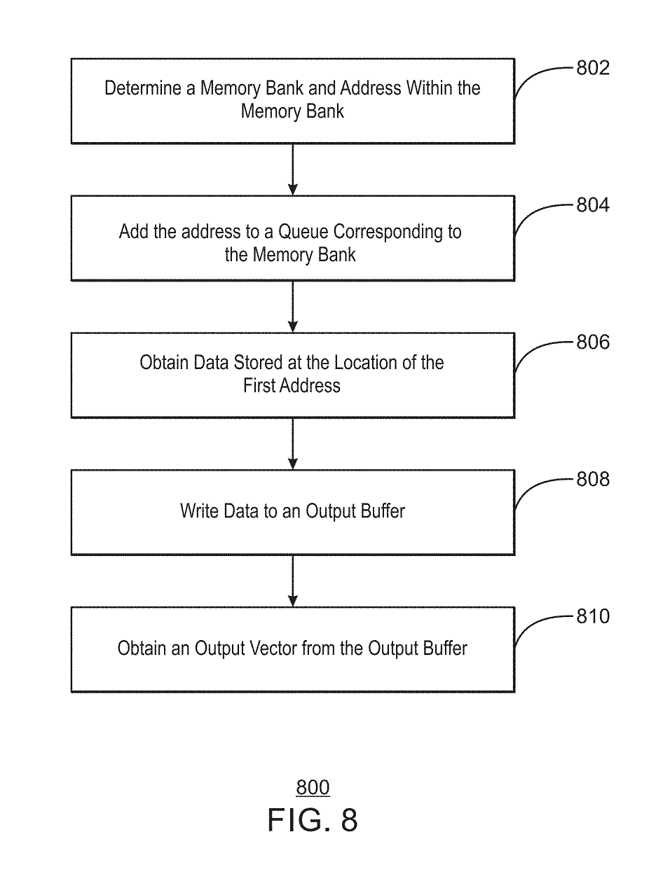

FIG. 8 is a process flow diagram of a method 800 for localized and random data access. At block 802, a memory bank and address within the memory bank is determined. In embodiments, a skew factor may be used to determine the memory bank and the address within the memory bank. At block 804, the address is added to a queue corresponding to a memory bank. In embodiments, the queue may be a FIFO queue. At block 806, the first address in the queue is used to obtain data stored at the location of the first address. At block 808, the data is written to an output buffer. At block 810, an output vector is output from the output buffer when all data is available.

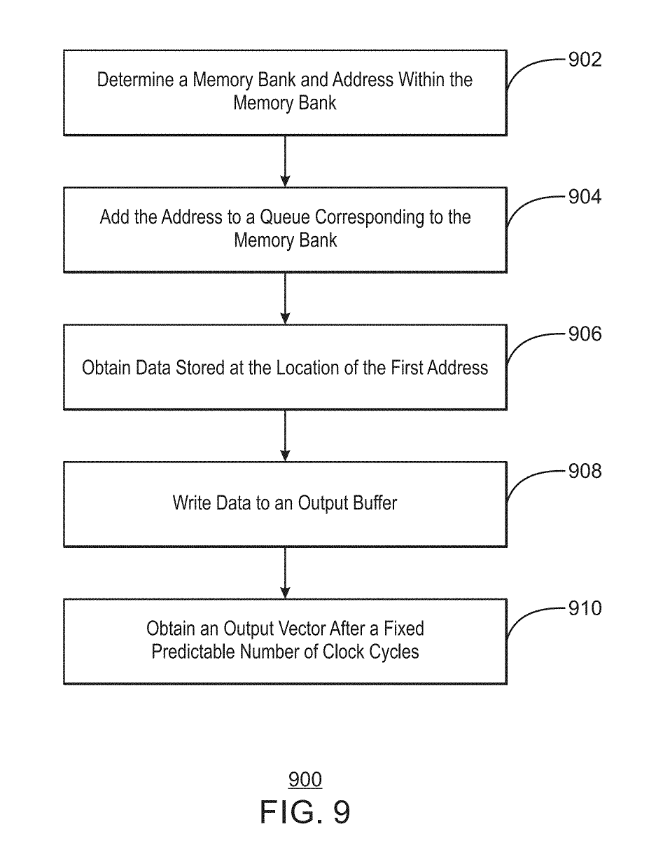

FIG. 9 is a process flow diagram of a method 900 for localized and random data access. At block 902, a memory bank and address within the memory bank is determined. In embodiments, a skew factor may be used to determine the memory bank and the address within the memory bank. At block 904, the address is added to a queue corresponding to a memory bank. In embodiments, the queue may be a FIFO queue. At block 906, the first address in the queue is used to obtain data stored at the location of the first address. At block 908, the data is written to an output buffer. At block 910, an output vector is output from the output buffer after a fixed predictable number of clock cycles.

The process flow diagram of FIGS. 8 and 9 are not intended to indicate that the blocks of methods 800 and 900 are to be executed in any particular order, or that all of the blocks are to be included in every case. Further, any number of additional blocks may be included within the methods 800 and 900, depending on the details of the specific implementation. Additionally, while the methods described herein include a GPU, the memory may be shared between any I/O device such as another CPU or a direct memory access (DMA) controller.

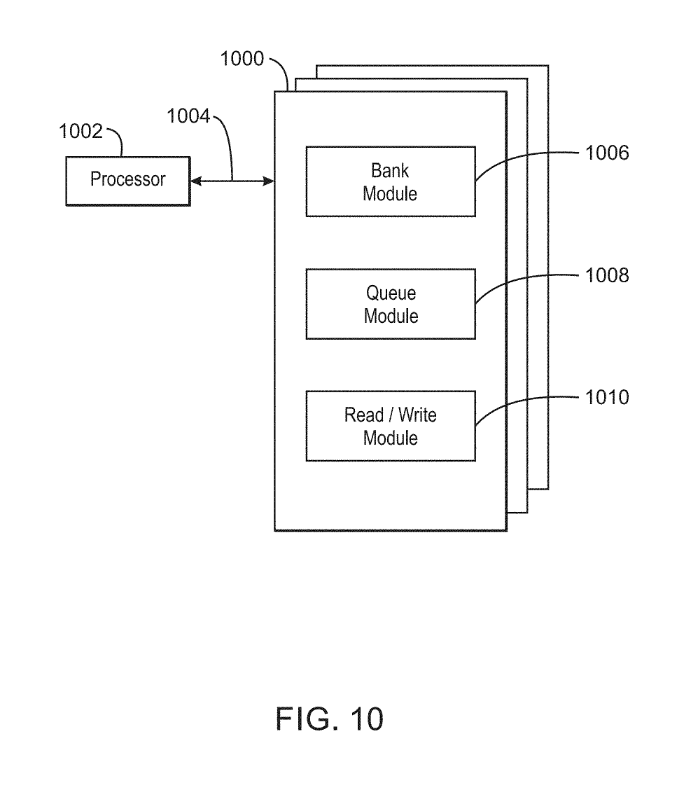

FIG. 10 is a block diagram showing tangible, non-transitory computer-readable media 1000 that stores code for localized and random data access. The tangible, non-transitory computer-readable media 1000 may be accessed by a processor 1002 over a computer bus 1004. Furthermore, the tangible, non-transitory computer-readable media 1000 may include code configured to direct the processor 1002 to perform the methods described herein.

The various software components discussed herein may be stored on the tangible, non-transitory computer-readable media 1000, as indicated in FIG. 10. For example, a bank module 1006 may be configured to determine a memory bank and an address within the bank for data access. In embodiments, a skew may be applied to the addresses. A queue module 1008 may be configured to store the addresses. Further, a read/write module 1010 may be configured to read or write data based on addresses from the queue.

The block diagram of FIG. 10 is not intended to indicate that the tangible, non-transitory computer-readable media 1000 is to include all of the components shown in FIG. 10. Further, the tangible, non-transitory computer-readable media 1000 may include any number of additional components not shown in FIG. 10, depending on the details of the specific implementation.

To show the value of this proposal the following simulation is performed. Three different access pattern are generated: (1) Completely random (typical for some computer vision and machine learning algorithms); (2) Random positioned blocks of 4×4 pixels (typical for computational imaging algorithms); and (3) Random grouped access—center position chosen randomly and then pixels in the neighborhood accessed randomly (typical for some object detection or/and tracking computer vision algorithms).

For this example, a 2D data space of 256×256 samples is used and Nb=16 memory banks. The BA memory of IPU can efficiently fetch blocks but is very inefficient for other access patterns. By combining the skewed memory addressing of the IPU BA memory and the scheduling according to the present techniques, the block patterns are read as efficiently as the BA memory but the random patterns also.

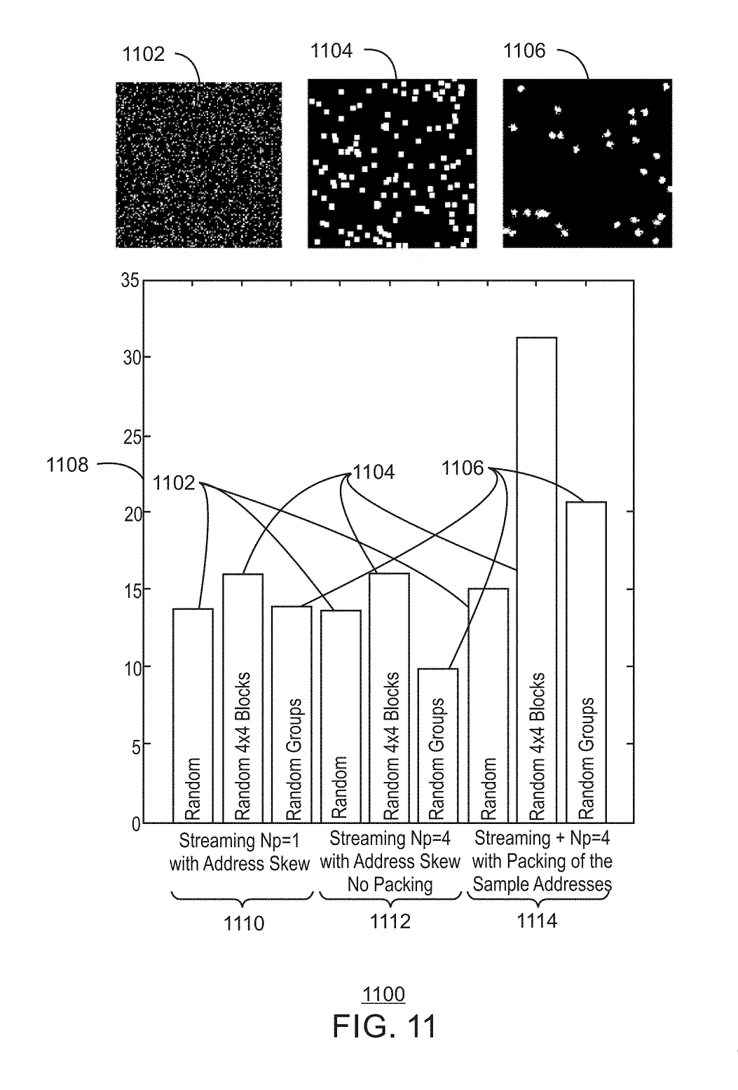

FIG. 11 is a chart illustrating the performance of three example random data memory types in terms of an average samples per clock read from three example types of data access patterns. The chart is generally referenced using the reference number 1100.

In the chart 1100, three example data access patterns include a random pattern 1102, a random block pattern 1104, and random groups 1106 are shown. As used herein, random groups refer to different irregular shapes, where pixels are close to each other. The vertical axis of graph 1100 represents performance as average samples per clock (SPCs).

The chart 1100 shows the performance of three example data memory types including single sample wide memory 1110, multi-sample wide memory 1111 with 4 sample wide memory banks without scheduling, and multi-sample wide memory with scheduling 1114. Skewing of data is enabled in order to allow the random block pattern 1104 and random groups 1106 to benefit from the skewing feature. The depth of each queue is eight addresses. In embodiments, 816 banks is the same buffer of addresses as above examples, where Nva=4*32.

As shown in FIG. 11, the first three columns 1110 represent the performance of a single-sample wide memory 1110. In particular, 4×4 groups may benefit particularly from the address skewing. In the second three columns, a four sample wide set of memory banks were used but only one pixel was used from the read batch. The performance for the random samples and random 4×4 blocks was unaffected, while the random groups' performance suffered due to bank conflicts that were not present in the case of single sample wide memory banks. The third group 1114 shows the performance increase when all Np×Nb pixels read are utilized. The random groups show an increase in performance from 14 SPC to 22 SPC, or an increase of 57%. The random block reads show improvement from 16 to 31 SPC. Thus, the processing of images with random blocks and random groups may be particularly benefitted by including multi-sample wide memory banks and skewed addressing with address scheduling.

Example 1 is an apparatus for localized and random data access. The apparatus includes a multi-bank memory to store a plurality of addresses of imaging data; a plurality of queues that correspond to each bank of the multi-bank memory, wherein each queue is to store addresses and corresponding information from the multi-bank memory for data access; an output buffer to store data accessed based on addresses in each respective queue.

Example 2 includes the apparatus of example 1, including or excluding optional features. In this example, the plurality of addresses are stored in the multi-bank memory based on a skew factor.

Example 3 includes the apparatus of any one of examples 1 to 2, including or excluding optional features. In this example, each queue of the plurality of queues are first in, first out queues.

Example 4 includes the apparatus of any one of examples 1 to 3, including or excluding optional features. In this example, the data access is a data read and the corresponding information is a target location for the imaging data to be read.

Example 5 includes the apparatus of any one of examples 1 to 4, including or excluding optional features. In this example, the data access is a data write and the corresponding information is the imagining data to be written to an address.

Example 6 includes the apparatus of any one of examples 1 to 5, including or excluding optional features. In this example, the multi-bank memory comprises single-sample wide memory banks.

Example 7 includes the apparatus of any one of examples 1 to 6, including or excluding optional features. In this example, the multi-bank memory comprises multi-sample wide memory banks.

Example 8 includes the apparatus of any one of examples 1 to 7, including or excluding optional features. In this example, the plurality of queues are to store a continuous stream of addresses from the multi-bank memory for data access.

Example 9 includes the apparatus of any one of examples 1 to 8, including or excluding optional features. In this example, the multi-bank memory comprises a number of memory banks corresponding to a number of samples that can be processed in parallel by an associated processor.

Example 10 includes the apparatus of any one of examples 1 to 9, including or excluding optional features. In this example, the apparatus includes an address history, wherein an address scheduler is to assign an address from the plurality of addresses to each bank of the multi-bank memory based on the address history.

Example 11 is a method for localized and random data access. The method includes storing a plurality of addresses in a multi-bank memory; placing the plurality of addresses from the multi-bank memory for data access in a queue from a plurality of queues, wherein each queue corresponds to each bank of the multi-bank memory; transferring corresponding information from each queue to an output buffer; and outputting data from the output buffer.

Example 12 includes the method of example 11, including or excluding optional features. In this example, the plurality of addresses are stored in a respective bank of the multi-bank memory based on a skewed address logic.

Example 13 includes the method of any one of examples 11 to 12, including or excluding optional features. In this example, the data access is a data read and the corresponding information is a target location for data to be read. Optionally, the data is transferred to the output buffer in an order not indicated by the placing of the plurality of addresses. Optionally, the data is transferred to the output buffer in a same order as indicated by the placing of the plurality of addresses.

Example 14 includes the method of any one of examples 11 to 13, including or excluding optional features. In this example, the data access is a data write and the corresponding information is data to be written to an address.

Example 15 includes the method of any one of examples 11 to 14, including or excluding optional features. In this example, the method includes placing the plurality of addresses from the multi-bank memory for data access in the plurality of queues is a continuous manner.

Example 16 includes the method of any one of examples 11 to 15, including or excluding optional features. In this example, the multi-bank memory is a scratchpad memory with multi-level buffering.

Example 17 includes the method of any one of examples 11 to 16, including or excluding optional features. In this example, the method includes a data write as the data access, wherein the corresponding information is data to be written to an address is a memory access pattern to minimize the chance that samples from a same memory bank are organized in distinct access patterns.

Example 18 includes the method of any one of examples 11 to 17, including or excluding optional features. In this example, the plurality of addresses are stored in a respective bank of the multi-bank memory based on a skewed address logic that comprises calculating a skew factor based on dimensions of a matrix to store the plurality of addresses.

Example 19 is a system for localized and random data access. The system includes a memory, wherein in the memory is divided into a multi-bank memory; and a processor coupled to the memory, the processor to: store a plurality of addresses in the multi-bank memory; place the plurality of addresses from the multi-bank memory for data access in a queue from a plurality of queues, wherein each queue corresponds to each bank of the multi-bank memory; transfer corresponding information from each queue to an output buffer; and output data from the output buffer.

Example 20 includes the system of example 19, including or excluding optional features. In this example, the plurality of addresses are stored in a respective bank of the multi-bank memory based on a skewed address logic.

Example 21 includes the system of any one of examples 19 to 20, including or excluding optional features. In this example, the data access is a data read and the corresponding information is a target location for data to be read. Optionally, the data is transferred to the output buffer in an order not indicated by the placing of the plurality of addresses. Optionally, the data is transferred to the output buffer in a same order as indicated by the placing of the plurality of addresses.

Example 22 includes the system of any one of examples 19 to 21, including or excluding optional features. In this example, the data access is a data write and the corresponding information is data to be written to an address.

Example 23 includes the system of any one of examples 19 to 22, including or excluding optional features. In this example, the system includes placing the plurality of addresses from the multi-bank memory for data access in the plurality of queues is a continuous manner.

Example 24 includes the system of any one of examples 19 to 23, including or excluding optional features. In this example, the multi-bank memory is a scratchpad memory with multi-level buffering.

Example 25 includes the system of any one of examples 19 to 24, including or excluding optional features. In this example, the system includes a data write as the data access, wherein the corresponding information is data to be written to an address is a memory access pattern to minimize the chance that samples from a same memory bank are organized in distinct access patterns.

Example 26 includes the system of any one of examples 19 to 25, including or excluding optional features. In this example, the plurality of addresses are stored in a respective bank of the multi-bank memory based on a skewed address logic that comprises calculating a skew factor based on dimensions of a matrix to store the plurality of addresses.

Example 27 is at least one machine readable medium comprising a plurality of instructions that. The computer-readable medium includes instructions that direct the processor to store a plurality of addresses in a multi-bank memory; place the plurality of addresses from the multi-bank memory for data access in a queue from a plurality of queues, wherein each queue corresponds to each bank of the multi-bank memory; transfer corresponding information from each queue to an output buffer; and output data from the output buffer.

Example 28 includes the computer-readable medium of example 27, including or excluding optional features. In this example, the plurality of addresses are stored in a respective bank of the multi-bank memory based on a skewed address logic.

Example 29 includes the computer-readable medium of any one of examples 27 to 28, including or excluding optional features. In this example, the data access is a data read and the corresponding information is a target location for data to be read. Optionally, the data is transferred to the output buffer in an order not indicated by the placing of the plurality of addresses. Optionally, the data is transferred to the output buffer in a same order as indicated by the placing of the plurality of addresses.

Example 30 includes the computer-readable medium of any one of examples 27 to 29, including or excluding optional features. In this example, the data access is a data write and the corresponding information is data to be written to an address.

Example 31 includes the computer-readable medium of any one of examples 27 to 30, including or excluding optional features. In this example, the computer-readable medium includes placing the plurality of addresses from the multi-bank memory for data access in the plurality of queues is a continuous manner.

Example 32 includes the computer-readable medium of any one of examples 27 to 31, including or excluding optional features. In this example, the multi-bank memory is a scratchpad memory with multi-level buffering.

Example 33 includes the computer-readable medium of any one of examples 27 to 32, including or excluding optional features. In this example, the computer-readable medium includes a data write as the data access, wherein the corresponding information is data to be written to an address is a memory access pattern to minimize the chance that samples from a same memory bank are organized in distinct access patterns.

Example 34 includes the computer-readable medium of any one of examples 27 to 33, including or excluding optional features. In this example, the plurality of addresses are stored in a respective bank of the multi-bank memory based on a skewed address logic that comprises calculating a skew factor based on dimensions of a matrix to store the plurality of addresses.

Example 35 is an apparatus for localized and random data access. The apparatus includes instructions that direct the processor to a multi-bank memory to store a plurality of addresses of imaging data; a means to schedule and access data that is to add the plurality of addresses to a plurality of queues that correspond to each bank of the multi-bank memory, wherein each queue is to store addresses and corresponding information from the multi-bank memory for data access; an output buffer to store data accessed based on addresses in each respective queue.

Example 36 includes the apparatus of example 35, including or excluding optional features. In this example, the plurality of addresses are stored in a respective bank of the multi-bank memory based on a skewed address logic.

Example 37 includes the apparatus of any one of examples 35 to 36, including or excluding optional features. In this example, the data access is a data read and the corresponding information is a target location for data to be read. Optionally, the data is transferred to the output buffer in an order not indicated by the placing of the plurality of addresses. Optionally, the data is transferred to the output buffer in a same order as indicated by the placing of the plurality of addresses.

Example 38 includes the apparatus of any one of examples 35 to 37, including or excluding optional features. In this example, the data access is a data write and the corresponding information is data to be written to an address.

Example 39 includes the apparatus of any one of examples 35 to 38, including or excluding optional features. In this example, the apparatus includes placing the plurality of addresses from the multi-bank memory for data access in the plurality of queues is a continuous manner.

Example 40 includes the apparatus of any one of examples 35 to 39, including or excluding optional features. In this example, the multi-bank memory is a scratchpad memory with multi-level buffering.

Example 41 includes the apparatus of any one of examples 35 to 40, including or excluding optional features. In this example, the apparatus includes a data write as the data access, wherein the corresponding information is data to be written to an address is a memory access pattern to minimize the chance that samples from a same memory bank are organized in distinct access patterns.

Example 42 includes the apparatus of any one of examples 35 to 41, including or excluding optional features. In this example, the plurality of addresses are stored in a respective bank of the multi-bank memory based on a skewed address logic that comprises calculating a skew factor based on dimensions of a matrix to store the plurality of addresses.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. An apparatus for localized and random data access, comprising:
a multi-bank memory to store a plurality of addresses of imaging data;
a plurality of queues that correspond to each bank of the multi-bank memory, wherein each queue is to store addresses and corresponding information from the multi-bank memory for data access;
an output buffer to store data accessed based on addresses in each respective queue.

2. The apparatus of claim 1, wherein the plurality of addresses are stored in the multi-bank memory based on a skew factor.

3. The apparatus of claim 1, wherein each queue of the plurality of queues are first in, first out queues.

4. The apparatus of claim 1, wherein the data access is a data read and the corresponding information is a target location for the imaging data to be read.

5. The apparatus of claim 1, wherein the data access is a data write and the corresponding information is the imagining data to be written to an address.

6. The apparatus of claim 1, wherein the multi-bank memory comprises single-sample wide memory banks.

7. The apparatus of claim 1, wherein the multi-bank memory comprises multi-sample wide memory banks.

8. The apparatus of claim 1, wherein the plurality of queues are to store a continuous stream of addresses from the multi-bank memory for data access.

9. The apparatus of claim 1, wherein the multi-bank memory comprises a number of memory banks corresponding to a number of samples that can be processed in parallel by an associated processor.

10. The apparatus of claim 1, further comprising an address history, wherein an address scheduler is to assign an address from the plurality of addresses to each bank of the multi-bank memory based on the address history.

11. A method for localized and random data access, comprising:
storing a plurality of addresses in a multi-bank memory;
placing the plurality of addresses from the multi-bank memory for data access in a queue from a plurality of queues, wherein each queue corresponds to each bank of the multi-bank memory;
transferring corresponding information from each queue to an output buffer; and
outputting data from the output buffer.

12. The method of claim 11, wherein the plurality of addresses are stored in a respective bank of the multi-bank memory based on a skewed address logic.

13. The method of claim 11, wherein the data access is a data read and the corresponding information is a target location for data to be read.

14. The method of claim 11, wherein the data access is a data read and the corresponding information is a target location for data to be read, and the data is transferred to the output buffer in an order not indicated by the placing of the plurality of addresses.

15. The method of claim 11, wherein the data access is a data read and the corresponding information is a target location for data to be read, and the data is transferred to the output buffer in a same order as indicated by the placing of the plurality of addresses.

16. The method of claim 11, wherein the data access is a data write and the corresponding information is data to be written to an address.

17. A system for localized and random data access, comprising:
a memory, wherein in the memory is divided into a multi-bank memory; and
a processor coupled to the memory, the processor to:
store a plurality of addresses in the multi-bank memory;
place the plurality of addresses from the multi-bank memory for data access in a queue from a plurality of queues, wherein each queue corresponds to each bank of the multi-bank memory;
transfer corresponding information from each queue to an output buffer; and
output data from the output buffer.

18. The system of claim 17, comprising placing the plurality of addresses from the multi-bank memory for data access in the plurality of queues is a continuous manner.

19. The system of claim 17, wherein the multi-bank memory is a scratchpad memory with multi-level buffering.

20. The system of claim 17, comprising a data write as the data access, wherein the corresponding information is data to be written to an address in a memory access pattern to minimize the chance that samples from a same memory bank are organized in distinct access patterns.

21. The system of claim 17, wherein the plurality of addresses are stored in a respective bank of the multi-bank memory based on a skewed address logic that comprises calculating a skew factor based on dimensions of a matrix to store the plurality of addresses.

22. At least one machine readable medium comprising a plurality of instructions that, in response to being executed on a computing device, cause the computing device to:
store a plurality of addresses in a multi-bank memory;
place the plurality of addresses from the multi-bank memory for data access in a queue from a plurality of queues, wherein each queue corresponds to each bank of the multi-bank memory;
transfer corresponding information from each queue to an output buffer; and
output data from the output buffer.

23. The computer readable medium of claim 22, wherein the plurality of addresses are stored in a respective bank of the multi-bank memory based on a skewed address logic.

24. The computer readable medium of claim 22, wherein the data access is a data read and the corresponding information is a target location for data to be read.

25. The computer readable medium of claim 22, wherein the data access is a data write and the corresponding information is data to be written to an address.
